(19) United States
(12) Patent Application Publication
(10) Pub. No.: US 2023/0170434 A1
(43) Pub. Date: Jun. 1, 2023

(54) VERTICAL LIGHT-EMITTING DIODE AND METHOD FOR FABRICATING THE SAME

(71) Applicant: INGENTEC CORPORATION, Zhunan Township (TW)

(72) Inventors: AI SEN LIU, ZHUNAN TOWNSHIP (TW); HSIANG AN FENG, ZHUNAN TOWNSHIP (TW); HSIAO LU CHEN, ZHUNAN TOWNSHIP (TW); YI CHUAN HUANG, ZHUNAN TOWNSHIP (TW)

(21) Appl. No.: 17/852,113

(22) Filed: Jun. 28, 2022

(30) Foreign Application Priority Data
Nov. 26, 2021 (TW) 110144108

(51) Int. Cl. H01L 33/00; H01L 33/40; H01L 33/44

(52) U.S. Cl. CPC H01L 33/0066; H01L 33/0093; H01L 33/40; H01L 33/44; H01L 2933/0016; H01L 2933/0025

(57) ABSTRACT

A method for fabricating a vertical light-emitting diode includes: providing a growth substrate, wherein an epitaxial layer is formed on the growth substrate; forming a metal combined substrate on the epitaxial layer, wherein the metal combined substrate comprises two first metal layers and a second metal layer therebetween, one of the first metal layers is close to the epitaxial layer, and another of the first metal layers is far away from the epitaxial layer; removing the growth substrate; forming a contact metal layer on the epitaxial layer; and removing the second metal layer and the first metal layer far away from the epitaxial layer and leaving the first metal layer close to the epitaxial layer. The vertical light-emitting diode, fabricated by the method, has a thinner thickness, a stronger mechanical strength, a higher light intensity, and a better heat-dissipating effect.

This application claims priority of Application No. 110144108 filed in Taiwan on 26 Nov. 2021 under 35 U.S.C. § 119; the entire contents of all of which are hereby incorporated by reference.

### BACKGROUND OF THE INVENTION

### Field of the Invention

The present invention relates to a method for fabricating a light-emitting diode, particularly to a method for fabricating a vertical light-emitting diode.

### Description of the Related Art

With the increasing demands for thinner display panels, a liquid crystal display (LCD) that requires a backlight layer, a liquid crystal layer, and a polarizer can no longer meet such demands. Although self-luminous organic light-emitting diodes (OLEDs) can be made into thinner and bendable display panels, OLEDs have a shorter lifetime than LCDs due to the frequent migration of electrons to the light-emitting layer and the organic matters of the OLED. Therefore, panel manufacturers are working on developing micro LEDs, which have the advantages of LCD and OLED but have no disadvantages thereof. In the process of micro LEDs, it is necessary to perform a cutting process to obtain multiple epitaxial dies. Then, it is necessary to employ some technologies such as electrostatic transfer, micro-transfer printing, fluid assembly, and magnetic transfer, such that red, blue, and green light-emitting diodes are picked up from the intermediate substrate and released to the destination substrate. This process is called Mass Transfer.

As an example of a vertical light emitting diode, the conventional structure mainly includes a silicon substrate, an epitaxial layer bonded to the silicon substrate, and an electrode unit formed on the epitaxial layer. The thickness of the silicon substrate may be 100 μm, which is disadvantageous to implementing flimsy display panels. However, if the silicon substrate is removed and a copper substrate is directly bonded to the epitaxial layer, thermal stress occurs between the copper substrate and the epitaxial layer due to the mismatch of thermal expansion coefficients. Thermal stress may cause the epitaxial layer to protrude due to high shrinkage stress (i.e., pressure) or cause the epitaxial layer to crack and fall off due to tensile stress (i.e., tension). In order to avoid these drawbacks, copper is deposited on an accumulation layer using an electroplating method in the existing process. For example, Taiwan Patent Publication No. 1562404 disclosed a method of forming a light emitting diode structure, which states that “a conductive seed layer (i.e., Ni layer 524) allows thick copper electroplating or electroless deposition to form a copper layer 525, that the thickness of the electroless deposition or electroplated copper layer 528 can be higher than or equal to about 150 micrometer, and that the thickness is chosen such that the LED structure does not suffer from significant bowing or cracking during substrate removal for the layer transfer process”. However, through such a process, the thickness of copper electroplated on the epitaxial layer is greater than 150 μm, which not only disadvantages the flimsy display panel, but also greatly reduces the light-emitting effect of the light-emitting diode.

### SUMMARY OF THE INVENTION

The present invention provides a vertical light-emitting diode, which has a single metal layer. The metal layer has a low thickness, high thermal conductivity, and low heat capacity in order to dissipate heat and maintain a good light-emitting effect effectively.

In order to achieve these objectives, the present invention provides a method for fabricating a vertical light-emitting diode, which includes: providing a growth substrate, wherein an epitaxial layer is formed on the growth substrate; bonding a metal combined substrate on the epitaxial layer, wherein the metal combined substrate comprises two first metal layers and a second metal layer therebetween, one of the first metal layers is close to the epitaxial layer, and another of the first metal layers is far away from the epitaxial layer; removing the growth substrate; forming a contact metal layer on the epitaxial layer; and, removing the second metal layer and the first metal layer far away from the epitaxial layer and leaving the first metal layer close to the epitaxial layer.

In some embodiments, the epitaxial layer is etched to define a plurality of epitaxial structures, and the first metal layers and the second metal layer are divided according to locations of intervals among the plurality of epitaxial structures before the step of forming the contact metal layer on the epitaxial layer.

In some embodiments, the thermal expansion coefficient of each of the first metal layers is larger than that of the second metal layer, and the thickness of each of the first metal layers is less than that of the second metal layer.

In some embodiments, the ratio of the first metal layer to the second metal layer to the first metal layer in thickness is 1:2.5:1.

In some embodiments, the first metal layer includes copper and the second metal layer includes Invar.

In some embodiments, a protection layer that covers the first metal layer close to the epitaxial layer is provided before the step of removing the second metal layer and the first metal layer far away from the epitaxial layer.

In some embodiments, a passivation layer is formed on the epitaxial layer after the step of forming the contact metal layer on the epitaxial layer, wherein the contact metal layer emerges from the passivation layer.

In some embodiments, the second metal layer and the first metal layer far away from the epitaxial layer are removed with an etching solution that includes NH₄OH and H₂O₂.

The present invention also provides a vertical light-emitting diode fabricated by the method. The vertical light-emitting diode includes the first metal layer; the epitaxial layer formed on the first metal layer; and the contact metal layer formed on the epitaxial layer.

In some embodiments, the first metal layer includes copper and has a thickness of 10-20 μm.

Below, the embodiments are described in detail in cooperation with the drawings to make easily understood the technical contents, characteristics, and accomplishments of the present invention.

### BRIEF DESCRIPTION OF THE DRAWINGS

FIG. 1 is a flowchart of a method for fabricating a vertical light-emitting diode according to an embodiment of the present invention;

FIGS. 2-6 and 8-10 are cross-sectional views corresponding to FIG. 1;

FIG. 7 is a cross-sectional view corresponding to a method for fabricating a vertical light-emitting diode according to another embodiment of the present invention;

FIG. 11 is a cross-sectional view of a vertical light-emitting diode according to an embodiment of the present invention;

FIG. 12 is a diagram illustrating the physical properties of a conventional vertical light-emitting diode and a vertical light-emitting diode of the present invention;

FIG. 13 is a diagram illustrating the physical properties of a vertical light-emitting diode of the present invention; and

FIG. 14 is a diagram illustrating the physical properties of a conventional vertical light-emitting diode.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment.

Unless otherwise specified, some conditional sentences or words, such as “can”, “could”, “might”, or “may”, usually attempt to express that the embodiment in the present invention has, but it can also be interpreted as a feature, element, or step that may not be needed. In other embodiments, these features, elements, or steps may not be required.

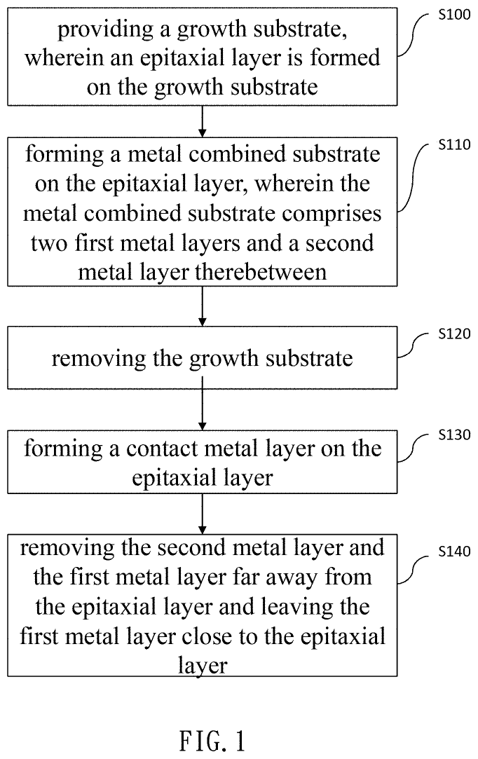

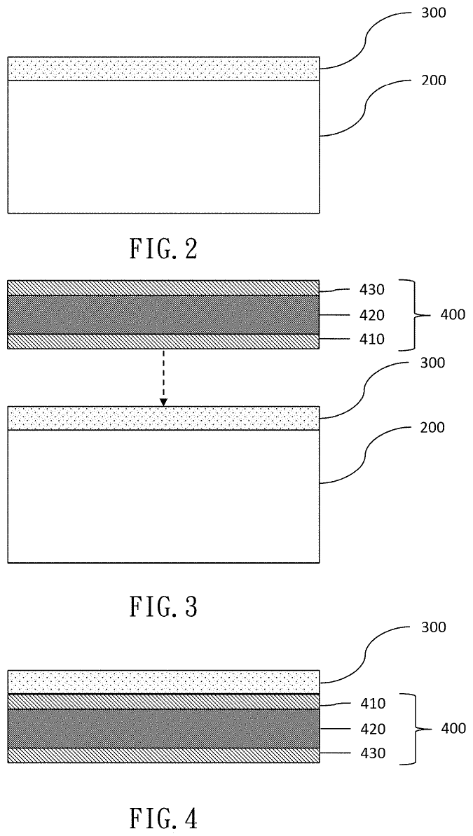

The present invention provides a method for fabricating a vertical light-emitting diode. A side of the vertical light-emitting diode has a single metal layer, and another side of the vertical light-emitting diode has a contact metal layer 500. Refer to FIG. 1. FIG. 1 is a flowchart of a method for fabricating a vertical light-emitting diode according to an embodiment of the present invention. In Step S100, a growth substrate 200 is provided. The growth substrate 200 has been treated by an epitaxial growth process in advance. Thus, an epitaxial layer 300 is formed on the growth substrate 200, as illustrated in FIG. 2. The epitaxial growth process may be performed using Chemical Vapor Deposition (CVD), Metal Organochemical Vapor Deposition (MOCVD), Vapor Epitaxy (VPE), Liquid Phase Epitaxy (LPE), or Molecular Beam Epitaxy (MBE). The epitaxial layer 300 as a light-emitting layer may include a buffer layer, a first semiconductor layer, an active layer, and a second semiconductor layer sequentially stacked. The buffer layer is grown on the growth substrate 200, such that the first semiconductor layer on the buffer layer has a lower defect density. The active layer is a multiple quantum well (MQW) for improving the recombination efficiency of electron-hole pairs. The first semiconductor layer and the second semiconductor layer are respectively an n-type semiconductor layer and a p-type semiconductor layer. Each of the first semiconductor layer and the second semiconductor layer has an energy gap larger than the energy gap of the active layer to concentrate carriers in the multiple quantum well. The following process is described by taking red light-emitting diodes as an example. In order to improve the lattice matching rate and reduce the occurrence of lattice dislocations, the growth substrate 200 can be a gallium arsenide (GaAs) substrate or a gallium phosphide (GaP) substrate, and the epitaxial layer 300 can include III-V group semiconductors, such as aluminum gallium arsenide (AlGaAs), gallium arsenide phosphide (GaAsP), aluminum indium gallium phosphide (AlGaInP), or gallium phosphide. However, the present invention should not be limited to red light-emitting diodes. The method of the present invention can be applied to fabricate blue light-emitting diodes or green light-emitting diodes. Therefore, the growth substrate 200 can be a sapphire substrate (i.e., Al₂O₃), a silicon carbide (SiC) substrate, or gallium nitride (GaN) substrate, and the epitaxial layer 300 can include III-V group semiconductors, such as gallium nitride, indium gallium nitride (InGaN), or aluminum gallium nitride (AlGaN). In addition, the method of the present invention can also be applied to fabricate optoelectronic components such as infrared light-emitting diodes or vertical resonant cavity surface emitting lasers (VCSELs). As a result, the epitaxial layer 300 may include a Bragg reflector (DBR) and a light-emitting active layer, respectively used as an upper layer and a lower layer.

In Step S110, a metal combined substrate 400 is bonded on the epitaxial layer 300, as illustrated in FIG. 3. The metal combined substrate 400, formed by MOCVD, laser cutting, vacuum heating, and grinding and polishing, includes a first metal layer 410, a second metal layer 420, and a first metal layer 430 sequentially stacked. The first metal layer 410 is close to the epitaxial layer 300, and the first metal layer 430 is far away from the epitaxial layer 300. The second metal layer 420 is stacked between the first metal layer 410 and the first metal layer 430. The thermal expansion coefficient of each of the first metal layers 410 and 430 is larger than that of the second metal layer 420. In the embodiment, the grinding and polishing can be implemented with chemical mechanical polishing (CMP) or copper metal polishing in the semiconductor process. No matter which grinding and polishing method is used, the surface of the first metal layer 410 can be polished to have a surface roughness of 0.5-0.01 μm. Thus, the surface of the first metal layer 410 can be used as a bonding surface that touches the epitaxial layer 300. In the embodiment, the laser cutting is performed using a UV laser (whose wavelength is 266 nm). Under the pressure of 100-250 torr, the vacuum heating is performed at 150-250° C. for 10-30 minutes, so as to relieve the stress of the metal combined substrate 400. In some embodiments, the first metal layers 410 and 430 include the same metal material and have the same thickness in order to effectively control the thermal expansion coefficient of the metal combined substrate 400. The second metal layer 420 includes another metal material and has a thickness larger than the thickness of the first metal layer 410. The first metal layers 410 and 430 and the second metal layer 420 may be formed using deposition or CMP. In order to adjust the thermal expansion coefficient of the metal combined substrate 400 to be equal to the thermal expansion coefficient of the epitaxial layer 300, the ratio of the first metal layer 410 to the second metal layer 420 to the first metal layer 430 in thickness is 1:2.5:1. Each of the first metal layers 410 and 430 may have a thickness of 10˜20 μm. Correspondingly, the thickness of the second metal layer 420 is 20˜60 μm. In some embodiments, the first metal layer 410 and the first metal layer 430 include copper, and the second metal layer 420 includes Invar. As a result, the metal combined substrate 400 is a copper-indium-copper (CIC) magnetic substrate. The magnetic substrate can be applied to vertical light-emitting diodes and has some technical advantages, such as low thermal expansion coefficient (6.1×10⁻⁶ K) and high thermal conductivity (180 W/mK).

In Step S120, the growth substrate 200 is removed using a semiconductor process, such as a lift-off process, a laser cutting process, a CMP process, or a wet-etching process, and the metal combined substrate 400 and the epitaxial layer 300 are reserved, as illustrated in FIG. 4. Then, the stacked structure is flipped over such that the positions of the epitaxial layer 300 and the metal combined substrate 400 are reversed. That is to say, the epitaxial layer 300 is formed on the top of the metal combined substrate 400, and the metal combined substrate 400 is formed on the bottom of the epitaxial layer 300, as illustrated in FIG. 4. The lift-off process may be a laser lift-off (LLO) process or a photoresist lift-off (PLO) process, but the present invention is not limited thereto. The LLO process may include the following steps: pre-coating a light-passing sacrifice layer (not illustrated) on the growth substrate 200 before forming the epitaxial layer 300 on the growth substrate 200, wherein the sacrifice layer should include organic materials that can be dissociated by laser, such as Benzocyclobutene; and then decomposing the sacrifice layer by irradiating the sacrifice layer with laser light, whereby the epitaxial layer 300 is lifted off from the growth substrate 200. When the growth substrate 200 is removed using a wet etching process, the epitaxial layer 300 should be prevented from being etched together. In order to achieve the purpose, it is necessary to use a chemical solution with a high selective etching ratio corresponding to the semiconductor material of the growth substrate 200. For example, a mixed solution including ammonia water (NH₄OH) and hydrogen peroxide (H₂O₂) is helpful in etching and removing GaAs substrates.

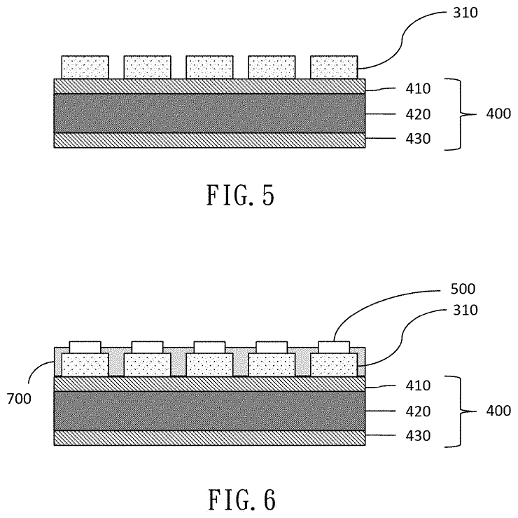

After Step S120, it can be understood that a single epitaxial structure (i.e., epitaxial layer 300) is obtained. However, it should be noted that, in an actual process, it is necessary to form a plurality of light-emitting diodes. In such a case, the epitaxial layer 300 needs to be etched to form a plurality of epitaxial structures 310, as illustrated in FIG. 5. Each epitaxial structure 310 is in the form of a mesa. There are intervals among the epitaxial structures 310. The etching process is called a mesa etching process, which includes the following steps: (1) performing a lithography process on the epitaxial layer 300 to define regions to be etched (e.g., the left and right sides of each epitaxial structure 310 illustrated in FIG. 5), wherein the lithography process mainly includes photoresist coating, exposure, and development processes, and baking and cooling processes can be selectively performed according to the needs of high resolution; and (2) performing a wet etching process on the regions to be etched. For example, the etching process is performed using a mixed solution that includes bromine and methanol.

In Step S130, a contact metal layer as an electrode unit of the vertical light-emitting diode is formed on the epitaxial structure using a lithography process and an etching process. As mentioned above, when the number of epitaxial structures 310 is multiple, a contact metal layer 500 is formed on each epitaxial structure 310 (as illustrated in FIG. 6). Preferably, the contact metal layer 500 can be made of metal mesh, carbon nanotube, graphene, or conductive polymer. The contact metal layer 500 may be a transparent conductive layer made of indium tin oxide (ITO) for increasing the light-emitting area of the epitaxial layer. The steps of the method of the present invention need not be in the exact order shown. In some embodiments, when the number of the epitaxial structures 310 is multiple, Step S130 is performed before the mesa etching process. Specifically, after lifting off the growth substrate 200 from the epitaxial layer 300, the stacked structure is flipped over such that the positions of the epitaxial layer 300 and the metal combined substrate 400 are reversed. That is to say, the epitaxial layer 300 is formed on the top of the metal combined substrate 400, and the metal combined substrate 400 is formed on the bottom of the epitaxial layer 300. Then, the contact metal layer 500 is formed on the epitaxial layer 300. A lithography process is performed to define at least one area to be etched of the contact metal layer 500. A dry etching process or a wet etching process is performed to remove the area to be etched. Then, in Step S130, the mesa etching process is performed on the epitaxial layer 300 to define a plurality of epitaxial structures 310. In the method for fabricating a vertical light emitting diode of the present invention, each area to be etched corresponds to one epitaxial structure 310.

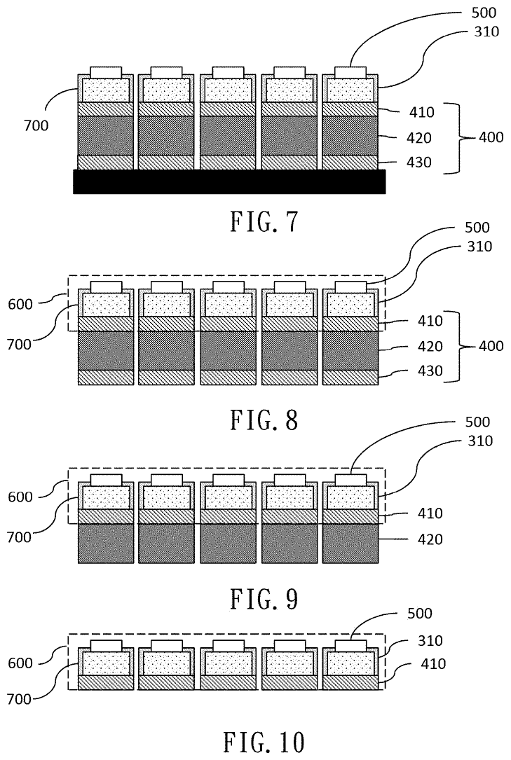

In some embodiments, when the number of the epitaxial structures 310 is two or more (as illustrated in FIG. 5 and FIG. 6), a cutting process is performed after Step S130. Specifically, the first metal layers 410 and 430 and the second metal layer 420 are divided according to the locations of intervals among the plurality of epitaxial structures 310 (as illustrated in FIG. 7). The cutting process may be a laser cutting process or a chemical cutting process. In order to avoid shifting the cutting locations due to the vibration of each epitaxial structure 310 and the metal combined substrate 400 thereunder during the cutting process, the metal combined substrate 400 can be pre-adhered to an ultraviolet tape (UV tape) before the cutting process. The UV tape can also prevent the epitaxial structure 310 from falling off or flying off during the cutting process. After the cutting process, the UV tape can be easily and cleanly removed by irradiating the UV tape with UV light to reduce the adhesion of the UV tape.

In some embodiments, after forming the contact metal layer 500, a passivation layer 700 is formed (as illustrated in FIG. 6). The passivation layer 700 covers a part of the contact metal layer 500 and areas other than the contact metal layer 500. In other words, the contact metal layer 500 emerges from the passivation layer 700 so that the upper surface of the contact metal layer 500 is exposed. The passivation layer 700 may include suitable materials, such as silicon nitride, silicon oxide, silicon oxynitride, or a combination of these. The passivation layer 700 may be formed using chemical vapor deposition, plasma-enhanced chemical vapor deposition (PECVD), atomic layer deposition (ALD), or other suitable processes.

In Step S140, the second metal layer 420 and the first metal layer 430 of the metal combined substrate 400 are removed, and the first metal layer 410 is reserved (as illustrated in FIGS. 8-10), so that a vertical light-emitting diode is obtained. Specifically, the first metal layer 430 is removed using an etching solution with high selectivity to copper, such as a mixed solution including citric acid and ammonium persulfate, as illustrated in FIG. 9. The second metal layer 420 is removed using an etching solution with high selectivity to Invar, such as a mixed solution including hydrogen peroxide and HNO₃, as illustrated in FIG. 10. In some embodiments, a protection layer 600 can be provided. The contact metal layer 500, the epitaxial structure 310, and the first metal layer 410 can be covered by the protection layer 600 in advance, lest the contact metal layer 500, the epitaxial structure 310, and the first metal layer 410 be removed together when etching the first metal layer 430 and the second metal layer 420 (as illustrated in the dotted area of FIGS. 8-10). The protection layer 600 can include a liquid wax or an acid-resistant and alkali-resistant gum. The formed protection layer 600 should at least extend to the sidewalls of the first metal layer 410 and the epitaxial layer 300. Even if the sidewalls of the second metal layer 420 and/or the first metal layer 430 are also covered by the protection layer 600, Step S410 can still be successfully completed. The reasons are explained as follows. The first metal layer 430 is etched using an etching solution with high selectivity to copper, wherein the etching solution does not etch the second metal layer 420 made of Invar. Thus, it is only necessary to avoid etching the sidewall of the first metal layer 410. On the other hand, the second metal layer 420 is etched using an etching solution with high selectivity to Invar. Although the etching solution does not etch the first metal layer 410 made of copper, the epitaxial structure 310 may be etched by the etching solution. As a result, the protection layer 600 extended to the sidewall of the epitaxial layer 300 can protect the epitaxial structure 310.

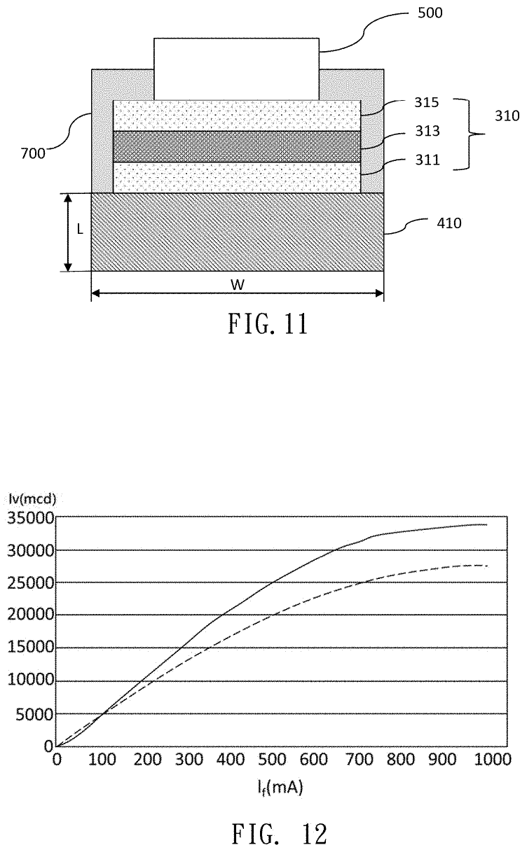

As illustrated in FIG. 11, the vertical light-emitting diode fabricated by the method includes the contact metal layers 500, the epitaxial structures 310, and the first metal layer 410. The contact metal layer 500 is formed on the upper surface of the epitaxial structure 310. The first metal layer 410 is formed on the lower surface of the epitaxial structure 310. In some embodiments, the first metal layer 410 may include copper and have a thickness L of 10˜20 μm. The epitaxial structure 310 includes an N-type semiconductor layer 311, a light-emitting layer 313, and a P-type semiconductor layer 315. The N-type semiconductor layer 311 may be a first AlGaInP layer, represented by n-AlGaInP. The light-emitting layer 313 may be a multiple quantum well layer. The P-type semiconductor layer 315 may be a second AlGaInP layer, represented by p-AlGaInP. In some embodiments, the vertical light-emitting diode further includes the passivation layer 700 that covers the epitaxial structures 310 and a part of the first metal layer 500.

Compared with the fabrication method of the present invention, a conventional method for fabricating a vertical light-emitting diode includes: providing a sapphire substrate, wherein an epitaxial layer is formed on the sapphire substrate, and an N-type semiconductor layer, a light emitting layer, a P-type semiconductor layer are sequentially stacked on the epitaxial layer; bonding a silicon substrate on the P-type semiconductor layer; flipping over and then performing an LLO process on the structures, wherein when a laser beam is irradiated on a junction between the N-type semiconductor layer and the sapphire substrate, the N-type semiconductor layer is lifted off from the sapphire substrate; and performing a mesa etching process on the epitaxial layer on the silicon substrate, forming electrode units, and performing a dice cutting process to form vertical light-emitting diodes. According to the foregoing description, the conventional vertical light-emitting diode includes the silicon substrate, the epitaxial layer on the silicon substrate, and the electrode unit on the epitaxial layer. In practice, the silicon substrate has a thickness of about 100 μm.

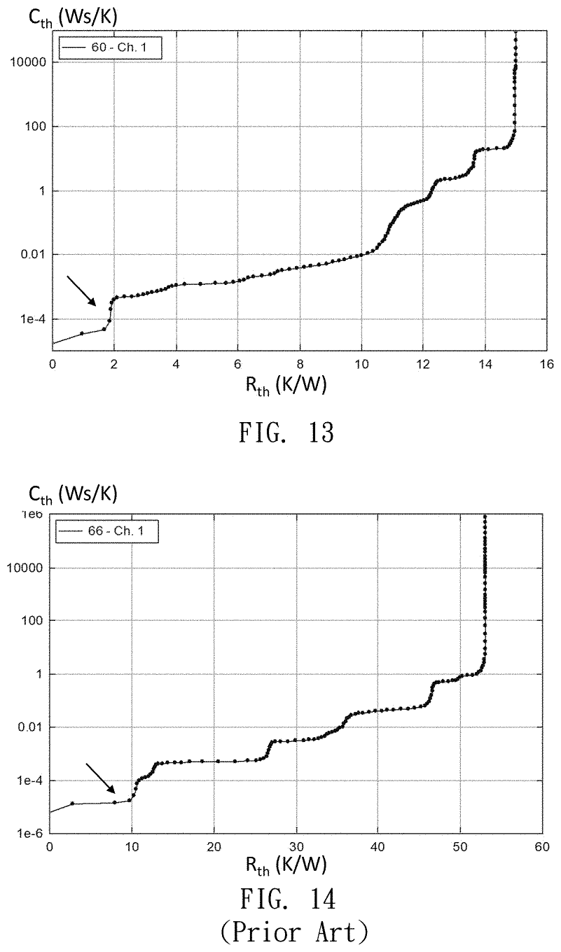

Compared with the conventional vertical light-emitting diode, the vertical light-emitting diode fabricating by the method of the present invention has a thinner thickness and a higher thermal conductivity coefficient. Refer to FIG. 12. FIG. 12 is a diagram illustrating the physical properties of a conventional vertical light-emitting diode. FIG. 12 shows a vertical axis in millicandelas (mcd) that represents the intensity of the light of the light-emitting diode after passing through the substrate. FIG. 12 shows a horizontal axis in milliamperes (mA) representing a current passing through the epitaxial layer 300. FIG. 12 shows a dotted line that corresponds to the silicon substrate of the conventional vertical light-emitting diode and a wavelength Wd of about 620 nm, wherein the silicon substrate has a thickness of about 100 μm. FIG. 12 shows a solid line that corresponds to the first metal layer 410 made of copper of the vertical light-emitting diode of the present invention and a wavelength Wd of about 620 nm, wherein the first metal layer 410 has a thickness of about 20 μm. From FIG. 12, it can be seen that the intensity of the light after passing through the silicon substrate and the first metal layer 410 respectively has 15000 mcd and 18450 mcd when a current of about 350 mA respectively passes through the conventional epitaxial layer and the epitaxial layer 300 of the present invention. The flimsy first metal layer 410 has 23% more light intensity than the silicon substrate. The intensity of the light after passing through the silicon substrate and the first metal layer 410 respectively has 27500 mcd and 34000 mcd when a current of about 1000 mA respectively passes through the conventional epitaxial layer and the epitaxial layer 300 of the present invention. On the other hand, the example uses the first metal layer 410 made of copper with a thermal conductivity coefficient of 380 W/m-K, which is better than the silicon substrate with a thermal conductivity coefficient of 190 W/m-K. Refer to FIG. 13 and FIG. 14. FIG. 13 is a diagram illustrating the physical properties of a vertical light-emitting diode of the present invention. FIG. 14 is a diagram illustrating the physical properties of a conventional vertical light-emitting diode. It should be noted that the arrows in FIG. 13 and FIG. 14 respectively represent the physical properties of the first metal layer 410 and the silicon substrate. The data on the right side of the arrows represent the physical properties of other packaging materials of the vertical light emitting diodes after the packaging process. According to data pointed by the arrows in FIG. 13 and FIG. 14, the first metal layer 410 has a thermal resistance of 0.053 K/W and a thermal capacity of not less than 0.0001 Ws/K, which is better than the silicon substrate having a thermal resistance of 0.526 K/W and a thermal capacity of less than 0.0001 Ws/K.

In conclusion, the vertical light-emitting diode formed by the fabrication method of the present invention has the following advantages: a thinner and lighter thickness, which is helpful in implementing the thinning of the display panel; a strong mechanical strength for improving the yield of the die-cutting and transferring processes: significant light intensity and better heat dissipation effect for avoiding the deformation of components caused by excessive temperature, and effectively maintaining a good light-emitting effect. It is worth mentioning that the fabrication method of the present invention can be applied to VSCELs, infrared light emitting diodes (IR LEDs), and other fabrication processes. For a person with ordinary skill in the art, the fabrication method of the present invention can be diverted without requiring undue experimentation. Therefore, any simple modification or diversion of the embodiment is applicable to the scope of the claims of the present invention.

The embodiments described above only exemplify the present invention but not limit the scope of the present invention. Therefore, any equivalent modification or variation according to the shapes, structures, features, or spirit disclosed by the present invention is to be also included within the scope of the present invention.

What is claimed is:

1. A method for fabricating a vertical light-emitting diode comprising:
providing a growth substrate, wherein an epitaxial layer is formed on the growth substrate;
bonding a metal combined substrate on the epitaxial layer, wherein the metal combined substrate comprises two first metal layers and a second metal layer therebetween, one of the first metal layers is close to the epitaxial layer, and another of the first metal layers is far away from the epitaxial layer;
removing the growth substrate;
forming a contact metal layer on the epitaxial layer; and
removing the second metal layer and the first metal layer far away from the epitaxial layer and leaving the first metal layer close to the epitaxial layer.

2. The method for fabricating a vertical light-emitting diode as in claim 1, further comprising etching the epitaxial layer to define a plurality of epitaxial structures and dividing the first metal layers and the second metal layer according to locations of intervals among the plurality of epitaxial structures before the step of forming the contact metal layer on the epitaxial layer.

3. The method for fabricating a vertical light-emitting diode as in claim 1, wherein a thermal expansion coefficient of each of the first metal layers is larger than that of the second metal layer, and a thickness of each of the first metal layers is less than that of the second metal layer.

4. The method for fabricating a vertical light-emitting diode as in claim 3, wherein a ratio of the first metal layer to the second metal layer to the first metal layer in thickness is 1:2.5:1.

5. The method for fabricating a vertical light-emitting diode as in claim 3, wherein the first metal layer comprises copper and the second metal layer comprises Invar.

6. The method for fabricating a vertical light-emitting diode as in claim 1, further comprising providing a protection layer that covers the first metal layer close to the epitaxial layer before the step of removing the second metal layer and the first metal layer far away from the epitaxial layer.

7. The method for fabricating a vertical light-emitting diode as in claim 1, further comprising forming a passivation layer on the epitaxial layer after the step of forming the contact metal layer on the epitaxial layer, wherein the contact metal layer emerges from the passivation layer.

8. The method for fabricating a vertical light-emitting diode as in claim 1, wherein the second metal layer and the first metal layer far away from the epitaxial layer are removed with an etching solution that includes NH₄OH and H₂O₂.

9. A vertical light-emitting diode, fabricated by the method as in any one of the preceding claims, comprising:
the first metal layer;
the epitaxial layer formed on the first metal layer; and
the contact metal layer formed on the epitaxial layer.

10. The vertical light-emitting diode as in claim 1, wherein the first metal layer comprises copper and has a thickness of 10˜20 μm.
